(19) United States
(12) Patent Application Publication
(10) Pub. No.: US 2013/0301196 A1
(43) Pub. Date: Nov. 14, 2013

(54) TOUCH PANEL

(71) Applicants: Shinichi Miyazaki, Osaka (JP); Kiyoshi Inada, Osaka (JP); Mikihiro Noma, Osaka (JP)

(72) Inventors: Shinichi Miyazaki, Osaka (JP); Kiyoshi Inada, Osaka (JP); Mikihiro Noma, Osaka (JP)

(73) Assignee: SHARP KABUSHIKI KAISHA, Osaka (JP)

(21) Appl. No.: 13/976,126

(22) PCT Filed: Dec. 20, 2011
(86) PCT No.: PCT/JP2011/079509

§ 371 Date: Jul. 11, 2013

(30) Foreign Application Priority Data
Dec. 27, 2010 (JP) 2010-290583

(51) Int. Cl. H05K 7/02

(52) U.S. Cl. CPC H05K 7/02
USPC 361/679.01

(57) ABSTRACT

Provided is a touch panel having a panel substrate that has overall flexibility and that has a panel part, whereupon electrode pads are disposed, and a protrusion part, whereupon terminals are disposed, formed integrally with each other, obtaining a configuration whereby the connection section between the panel part and the protrusion part is not easily damaged. A touch panel (2) is provided with: a substrate (11) that has overall flexibility and that has a touch panel substrate part (11a) and a connection part (11b) formed integrally with each other; a plurality of electrode pads (21a, 22a) that are disposed upon the touch panel substrate part (11a); and lead-out wiring lines (24) that externally output, from the connection part (11b), signals generated by the electrode pads (21a, 22a). To improve strength, a protective layer (14) is disposed on the operation screen side of the connection section between the touch panel substrate part (11a) and the connection part (11b).

### TECHNICAL FIELD

The present invention relates to a touch panel that is capable of detecting touch location on an operation screen.

### BACKGROUND ART

Conventionally, touch panels are known which can detect the location of where a pen, finger, or the like has touched on an operation screen, i.e., the touch location. Such a touch panel has a panel part in which electrodes are disposed, and a protrusion part (a tail part) having terminals disposed therein and formed integrally with the panel part, as disclosed in Japanese Patent Application Laid-Open Publication No. 2007-18226, for example. Disclosed in Japanese Patent Application Laid-Open Publication No. 2007-18226 is a technology in which a substrate constituted of a panel part and a protrusion part is made of a flexible substrate.

### SUMMARY OF THE INVENTION

However, the configuration disclosed in the aforementioned Japanese Patent Application Laid-Open Publication No. 2007-18226 can be easily deformed because the substrate is made of a flexible substrate. When the substrate is deformed, stress concentrates on the connection section between the panel part and protrusion part of the substrate. Therefore, there is a possibility that the connection section will be damaged if excessive force is applied to the connection section.

Thus, the embodiments below aim at providing, in a touch panel equipped with a panel substrate that has overall flexibility and that is obtained by integrally forming a panel part having electrodes disposed therein with a protrusion part having terminals disposed therein, a configuration in which a connection section between the panel part and the protrusion part is not easily damaged.

According to one embodiment of the present invention, a touch panel is provided with: a panel substrate having flexibility, the panel substrate including a panel part and a protrusion part formed integrally with the panel part; a plurality of electrode pads disposed on the panel part so as to be capable of detecting a touch location; lead-out wiring lines disposed on the panel part and the protrusion part, the lead-out wiring lines being electrically connected to the electrode pads and outputting signals generated in the electrode pads to an exterior from the protrusion part; and a transparent protective layer for improving strength disposed on an operation screen side of a connection section between the panel part and the protrusion part.

With the touch panel according to one embodiment of the present invention, the strength of the connection section between the panel part and the protrusion part can be improved with the protective layer, and damage to the connection section can be prevented.

### BRIEF DESCRIPTION OF THE DRAWINGS

FIG. 1 is a view schematically showing an overall configuration of a liquid crystal display device with a touch panel attached, which is provided with a touch panel according to Embodiment 1.

FIG. 2 is a plan view showing a schematic configuration of the touch panel.

FIG. 3 is a cross-sectional view along the line III-III in FIG. 2.

FIG. 4 is a cross-sectional view along the line IV-IV in FIG. 2.

FIG. 5 is a view of a touch panel according to Embodiment 2, corresponding to FIG. 4.

FIG. 6 is a plan view showing an arrangement of a protective plate.

FIG. 7 is a plan view showing a schematic configuration of a touch panel according to Embodiment 3.

FIG. 8 is a cross-sectional view along the line VIII-VIII in FIG. 7.

### DETAILED DESCRIPTION OF EMBODIMENTS

According to one embodiment of the present invention, a touch panel is provided with: a panel substrate having flexibility, the panel substrate including a panel part and a protrusion part formed integrally with the panel part; a plurality of electrode pads disposed on the panel part so as to be capable of detecting a touch location; lead-out wiring lines disposed on the panel part and the protrusion part, the lead-out wiring lines being electrically connected to the electrode pads and outputting signals generated by the electrode pads to an exterior from the protrusion part; and a transparent protective layer for improving strength disposed on an operation screen side of a connection section between the panel part and the protrusion part (First configuration).

According to the above-mentioned configuration, the strength of the connection section between the panel part and the protrusion part on a flexible panel substrate can be improved by a protective layer. When a deformation occurs in the panel substrate, stress will be concentrated on the connection section between the panel part and the protrusion part, but because of the presence of the protective layer described above, damaging of the connection section due to stress being exerted on the connection section can be prevented.

In the aforementioned first configuration, it is preferable for the protective layer to also be formed on the panel part (second configuration). By providing the protective layer on the panel part as described above, it is possible to prevent the electrode pads on the panel part from corroding or from being susceptible to the effect of external humidity. In other words, by providing the protective layer described above, the environmental resistance of the touch panel can be improved.

In the aforementioned first or second configuration, it is preferable for the electrode pads to be made of indium tin oxide or indium gallium zinc oxide (third configuration). When the electrode pads are made of indium tin oxide or indium gallium zinc oxide, it is harder for the electrode pads to corrode or be influenced by the surrounding environment when compared to electrode pads made of a metal material such as an aluminum alloy. Thus, when the electrode pads are made of indium tin oxide or indium gallium zinc oxide, it is usually not necessary to provide a protective film or the like on the operation screen side. In contrast, in the third configuration described above, a protective film is also provided in a configuration that conventionally does not require a protective film, as in the first and second configurations described above. By doing this, the strength of the touch panel can be improved.

In any one configuration of the first to third configurations, it is preferable that the touch panel further include a protective plate provided on the protrusion part so as to overlap in the thickness direction (fourth configuration).

Thus, the strength of the protrusion part having the terminals of the lead-out wiring lines provided therein can be improved by the protective plate. Furthermore, with such a configuration, it is possible to mount the protrusion part of the touch panel substrate on another rigid substrate.

By adjusting the thickness of the protective plate, it is possible to easily adjust the thickness of the protrusion part.

Preferred embodiments of the touch panel will be described below with reference to the drawings. The dimensions of the components in each drawing are not intended to exactly reflect the dimensions of the actual components, the dimension ratios, and the like of each component.

### Embodiment 1

(Whole Configuration)

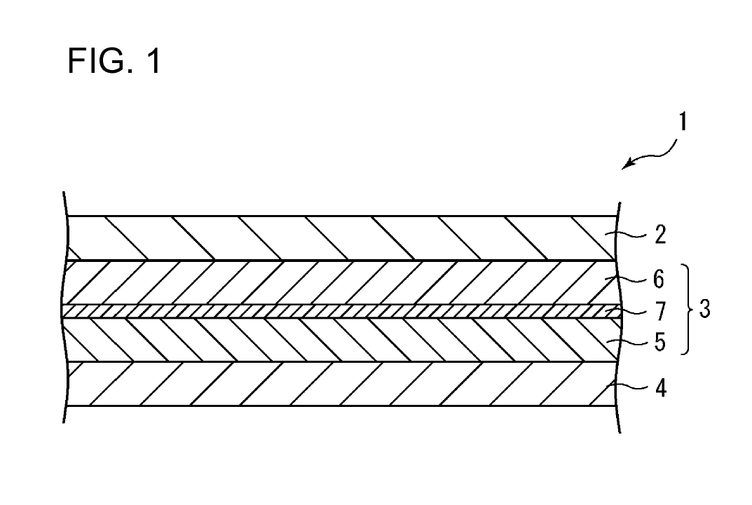

FIG. 1 shows a schematic configuration of a liquid crystal display device 1 with a touch panel attached, having been provided with a touch panel 2 according to Embodiment 1. As shown in FIG. 1, the liquid crystal display device 1 with a touch panel attached is made by superimposing a touch panel 2 capable of detecting touch locations on a liquid crystal panel 3 capable of displaying images. In FIG. 1, reference character 4 is a backlight. A cover glass covering a surface of the touch panel 2 on a side opposite to the liquid crystal panel 3 (the operation screen side, the viewer's side) and the like are not shown in the figure.

As shown in FIG. 1, the liquid crystal panel 3 is provided with an active matrix substrate 5 in which a large number of pixels are arranged in a matrix, and an opposite substrate 6 arranged opposing the active matrix substrate 5. The liquid crystal panel 3 is also provided with a liquid crystal layer 7 between the active matrix substrate 5 and the opposite substrate 6. This liquid crystal layer 7 may have any type of liquid crystal as long as the liquid crystal is capable of displaying images by the liquid crystal being controlled, and the operation mode of the liquid crystal may also be any mode. Although not specifically shown, a pair of polarizing plates is arranged on the liquid crystal panel 3 so as to sandwich the active matrix substrate 5 and the opposite substrate 6.

The active matrix substrate 5 is provided with a plurality of TFTs (Thin Film Transistors, not shown), pixel electrodes, a plurality of wiring lines (such as source wiring lines and gate wiring lines), and the like on a transparent substrate such as a glass substrate. The TFTs have a conventional configuration, and thus a detailed explanation is omitted.

The pixel electrodes are transparent electrodes, and are formed of a transparent conductive material such as ITO (Indium Tin Oxide) or IGZO (Indium Gallium Zinc Oxide), for example. The pixel electrodes are arranged spaced apart from each other, for each pixel. In other words, these pixel electrodes define the pixels, which serve as units of image display.

Although not specifically shown, the source electrodes, gate electrodes, and drain electrodes of the TFTs are respectively connected to the source wiring lines, gate wiring lines, and pixel electrodes. The technique in which the TFTs are driven by signals being inputted to the TFTs via the gate wiring lines and the source wiring lines is the same as in conventional liquid crystal display devices, and thus a detailed explanation is omitted.

The opposite substrate 6 is provided with an opposite electrode made of a transparent conductive material such as ITO or IGZO, and the like on a transparent substrate such as a glass substrate. When the liquid crystal panel 3 is a liquid crystal panel capable of displaying color images, RGB color filters are provided on the opposite substrate.

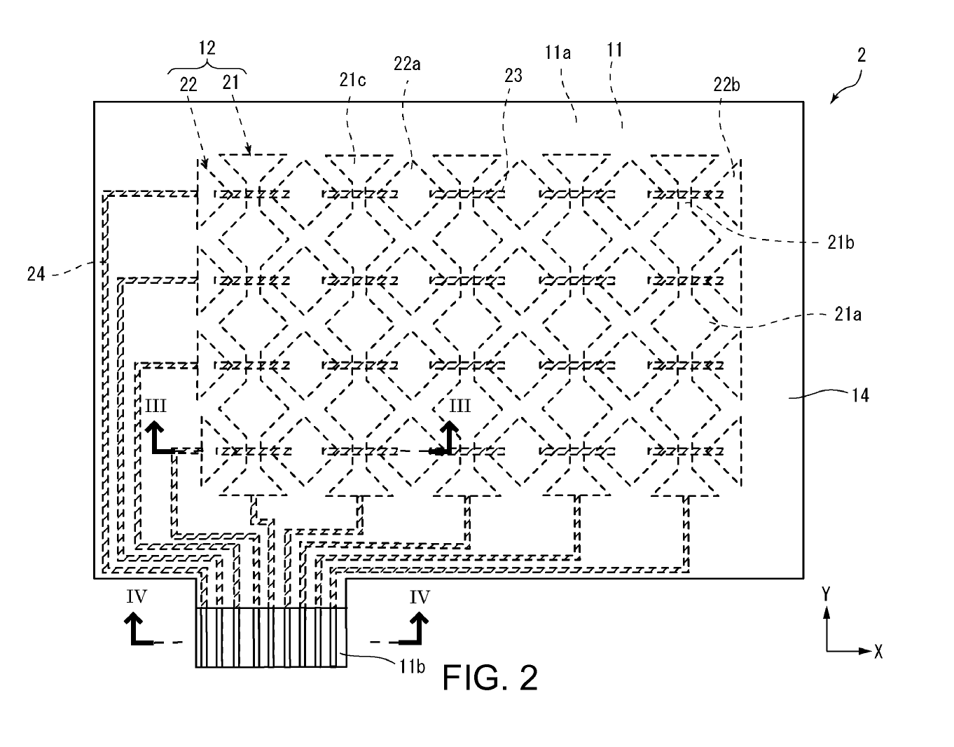

The touch panel 2 is provided with electrodes 12 on the operation screen side so as to be able to detect a location on the operation screen that has been touched (see FIG. 2). The touch panel 2 of the present embodiment is configured to use capacitance formed between the touch electrodes 12 and the finger that touches the operation screen, and detects the touch location based on a change in capacitance between the touch electrodes 12 and the finger, which occurred in the touch location. In other words, the touch panel 2 of the present embodiment is a so-called capacitive touch panel.

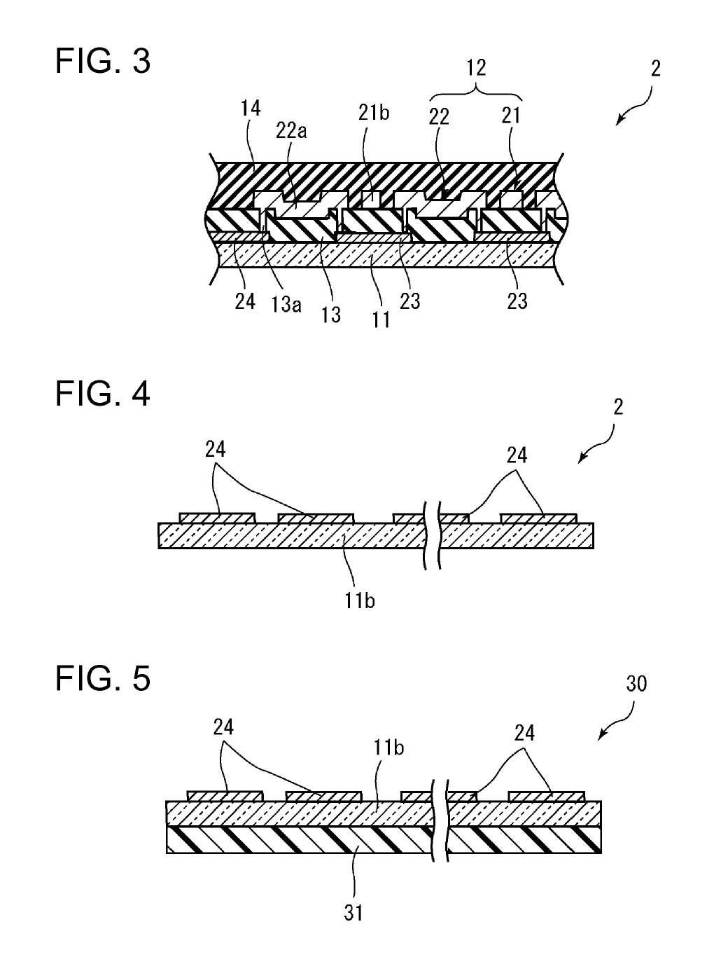

Specifically, as shown in FIG. 3, the touch panel 2 is provided with: a substrate 11; touch electrodes 12 formed on one surface side (the operation screen side, the operation side) of the substrate 11; an insulating layer 13 formed between the touch electrodes 12 and the substrate 11; and a protective layer 14 for protecting the touch electrodes 12.

The substrate 11 is a flexible substrate made of a transparent material having flexibility, such as polyethylene terephthalate (PET), polyethersulfone (PES), polyethylene naphthalate (PEN), or triacetylcellulose (TAC), for example. As shown in FIG. 2, this substrate 11 has a touch panel substrate part 11a (the panel part) in which the touch electrodes 12 are disposed, and a connection part 11b (the protrusion part) in which the ends of the lead-out wiring lines that connect to the touch electrodes 12 are positioned. This connection part 11b is formed integrally with the touch panel substrate 11a so as to protrude from one side of the touch panel substrate part 11a. As shown in FIG. 2, in this embodiment, the touch panel substrate part 11a is formed in a substantially rectangular shape, and the connection part 11b is provided on the lengthwise side of the touch panel substrate part 11a.

As shown in FIG. 2, the touch electrodes 12 include a plurality of electrode pads 21a and 22a formed in a substantially square shape, and a plurality of electrode pads 21c and 22b formed in a substantially triangular shape in a plan view. The touch electrodes 12 are constituted of the electrode pads 21a, 22a, 21c, and 22b being arranged at approximately equal spacing on the whole operation screen.

Furthermore, the touch electrodes 12 have X-direction electrodes 22 that extend in the X direction, and Y-direction electrodes 21 that extend in the Y direction in FIG. 2. These X-direction electrodes 22 and Y-direction electrodes 21 are made of a conductive material having transparent characteristics such as ITO or IGZO. As shown in FIG. 2, the X direction and the Y direction intersect with each other on the substrate 11 plane. In this embodiment, the X direction is the lengthwise direction of the substrate 11, and the Y direction is the widthwise direction of the substrate 11.

The Y-direction electrodes 21 are made by integrally forming Y-direction electrode pads 21a (the electrode pads), which are substantially quadrilateral in a plan view, with connection parts 21b that connect the Y-direction electrode pads 21a together. In other words, the Y-direction electrodes 21 have a long shape in the Y direction of FIG. 2.

Specifically, the Y-direction electrodes 21 have a shape in which the corner parts of the Y-direction electrode pads 21a are connected by the connection parts 21b in a state where a plurality of Y-direction electrode pads 21a are arranged so that the diagonal lines thereof match with the Y-direction. These Y-direction electrode pads 21a are arranged at equal distances in the Y direction. Furthermore, a plurality of Y-direction electrodes 21 are provided side by side in the X direction.

Y-direction electrode pads 21c that are substantially triangular-shaped in a plan view are provided on both lengthwise ends of the Y-direction electrodes 21. In other words, the Y-direction electrode pads 21c located on both lengthwise ends of the Y-direction electrodes 21 are approximately half the size of the other Y-direction electrode pads 21a.

As shown in FIG. 2, the X-direction electrodes 22 includes: X-direction electrode pads 22a (the electrode pads) that have a substantially quadrilateral shape, in a manner similar to the Y-direction electrode pads 21a described above, and that are the same size as the Y-direction electrode pads 21a; and bridge parts 23 that connect the X-direction electrode pads 22a together. Specifically, the X-direction electrodes 22 are constructed by connecting corners of a plurality of X-direction electrode pads 22a, which are arranged so that the diagonal lines thereof match with the X direction, by the bridge parts 23.

These X-direction electrode pads 22a are arranged at uniform distances in the X direction. The X-direction electrode pads 21a are arranged so as to sandwich the connection parts 21b of the Y-direction electrodes 21 at the corners. Thus, as shown in FIG. 2, the Y-direction electrode pads 21a and the X-direction electrode pads 22a are arranged on the whole operation screen at equal distances to each other.

X-direction electrode pads 22b that are substantially triangular-shaped are provided on both lengthwise ends of the X-direction electrodes 22, in a manner similar to the Y-direction electrode pads 21c located on both lengthwise ends of the Y-direction electrodes 21 described above. The X-direction electrode pads 22b are approximately half the size of the other X-direction electrode pads 22a.

These X-direction electrode pads 22a and 22b are made of a conductive material having transparent characteristics such as ITO or IGZO, in a manner similar to the Y-direction electrodes 21.

The bridge parts 23 are provided so as to connect the corners of the X-direction electrode pads 22a and 22b together, which are adjacent across the Y-direction electrodes 21. In other words, as shown in FIG. 2, the bridge parts 23 are arranged so as to cross the connection parts 21b of the Y-direction electrodes 21.

The bridge parts 23 are made of a metal wiring material such as an aluminum alloy, for example. The bridge parts 23 may also be made of a transparent conductive material such as ITO or IGZO, for example, in a manner similar to the Y-direction electrodes 21 and the X-direction electrode pads 22a and 22b.

As shown in FIG. 2, lead-out wiring lines 24 are connected to the substantially triangular shaped electrode pads 21c and 22b, which are located on one end of the lengthwise direction of the Y-direction electrodes 21 and X-direction electrodes 22. The lead-out wiring lines 24 are made of a metal wiring material such as an aluminum alloy, for example. The lead-out wiring lines 24 are formed so that the end on the opposite side of the end that connects to the Y-direction electrodes 21 and X-direction electrodes 22 is concentrated on the connection part 11b of the substrate 11. The end of the lead-out wiring lines 24 concentrated on the connection part 11b functions as a terminal for outputting signals to an external circuit or the like.

Next, a cross-sectional structure of the touch panel 2 will be explained using FIGS. 3 and 4. FIGS. 3 and 4 are a cross-sectional view along the line III-III and a cross-sectional view along the line IV-IV in FIG. 2, respectively.

As shown in FIG. 3, the bridge parts 23 for connecting the X-direction electrodes 22 together, and lead-out wiring lines 24 are provided on the substrate 11. In other words, the bridge parts 23 and lead-out wiring lines 24 are formed in the bottommost layer. The insulating layer 13 is provided on the substrate 11, the bridge parts 23, and the lead-out wiring lines 24. The Y-direction electrodes 21 and X-direction electrodes 22 made of a transparent conductive material such as ITO or IGZO are formed on the insulating layer 13. The protective layer 14 is provided so as to cover the Y-direction electrodes 21 and the X-direction electrodes 22.

The insulating layer 13 is made of an acrylic resin (such as the OPTMER-SS or NN series made by JSR Co., Ltd., for example). A contact hole 13a is formed in the insulating layer 13 for electrically connecting the X-direction electrodes 22 and the bridge parts 23 formed on the substrate 11. Thus, the X-direction electrodes 22 and Y-direction electrodes 21 can be formed in a different layer than the bridge parts 23. This makes it possible to have multi-level crossing between the bridge parts 23 connecting the X-direction electrode pads 22a, 22b together and the connection parts 21b of the Y-direction electrodes 21.

The protective layer 14 is made of an acrylic resin (such as the OPTMER-SS or NN series made by JSR Co., Ltd., for example), for example, in a manner similar to the insulating layer 13. In other words, this protective layer 14 is made of a transparent material having transparent characteristics. Furthermore, the protective layer 14 is made of a material having insulating characteristics, and flexibility in regards to bending. The protective layer 14 is made of material that is hard for water to permeate, and that has an antifouling effect.

As shown in FIGS. 2 and 3, the protective layer 14 is provided on the operation screen side of the touch panel 2. As shown in FIG. 2, the protective layer 14 is provided on the touch panel substrate part 11a and a portion of the connection part 11b of the substrate 11. Specifically, the protective layer 14 is formed on the whole touch panel substrate part 11a, along with being formed on a portion of the connection part 11b where the connection part 11b and the touch panel substrate 11a are connected to each other. The protective layer 14 is not provided on the distal side of the connection part 11b. As shown in FIG. 4, by not providing the protective layer 14 on the distal side of the connection part 11b as such, the lead-out wiring lines 24 are exposed on the distal side of the connection part 11b. Thus, the distal side of the connection part 11b can function as a terminal that contacts other wiring lines or the like.

As described above, the section where the touch panel substrate part 11a and the connection part 11b are connected to each other is covered by the protective layer 14, thereby making it possible to reinforce the relatively weak connection section. In other words, as described above, the substrate 11 is a flexible substrate where the touch panel substrate part 11a and the connection part 11b are formed integrally, and when the substrate 11 is deformed, stress will concentrate on the connection section. The substrate 11 is thin and made of a resin, so when stress is concentrated on the connection section, it is possible that cracking will occur on the connection section or that the connection section will be damaged. As a countermeasure, by covering the connection section with the protective layer 14 as described above, the strength of the connection section can be improved, and damage to the connection section can be prevented when the substrate 11 is deformed.

By covering the substrate 11 with the protective layer 14, except for the distal side of the connection part 11b that functions as an external terminal, it is possible to prevent the touch electrodes 12 and the lead-out wiring lines 24 from corroding or from being susceptible to the effect of surrounding humidity. Therefore, with the configuration described above, the environmental resistance of the touch panel 2 can be improved.

Furthermore, because the operation screen side is insulated by the protective layer 14, a structure for protecting the touch electrodes 12 and the like from electrostatic discharge can be simplified. With the protective layer 14, disconnection occurring with the touch electrodes 12 and the like at the time of operation of the touch panel 2 can be suppressed, along with it being possible to prevent the touch electrodes 12 from getting dirty or damaged.

Next, a manufacturing method for the touch panel 2 having a configuration as described above will be explained with reference to FIGS. 2 and 3.

First, the substrate 11 is formed in which the touch panel substrate part 11a and the connection part 11b are integrated. Then, a metal layer is formed by depositing an aluminum alloy using CVD (Chemical Vapor Deposition), sputtering, or the like on the touch panel substrate part 11a. By photolithography, a resist pattern is formed to cover areas (hereinafter, the planned formation areas) where the bridge parts 23 and the lead-out wiring lines 24 will be formed, and the metal layer is etched with the resist pattern as the mask. Thus, the bridge parts 23 and the lead-out wiring lines 24 as shown in FIG. 2 are obtained. Then, the formed resist pattern is removed.

Next, the insulating layer 13 is formed so as to cover the substrate 11, the bridge parts 23, and the lead-out wiring lines 24 (see FIG. 3). This insulating layer 13 is made of an acrylic resin or the like, for example. This insulating layer 13 is formed by spin coating or slit coating.

Next, a resist pattern that covers the areas other than the planned formation areas of the contact hole 13a is formed on the touch panel substrate part 11a by photolithography, and the insulating layer 13 is etched with this as the mask. Thus, the insulating layer 13 is removed, and the contact hole 13a is formed in the insulating layer 13, except for the portion on the touch panel substrate part 11a (see FIG. 3). Then, the resist pattern on the insulating layer 13 is removed.

A transparent metal film made of a transparent conductive material such as ITO or IGZO is formed on the insulating layer 13 by CVD, sputtering, or the like. By photolithography, a resist pattern is formed to cover the planned formation areas of the Y-direction electrodes 22 and the X-direction electrodes 23, and the transparent metal film is etched with this as the mask. Thus, the touch electrodes 12 as shown in FIG. 2 are obtained. Then, the formed resist pattern is removed.

Then, as shown in FIGS. 2 and 3, the protective layer 14 made of an acrylic resin, for example, is formed on the touch panel substrate part 11a, and the connection section between the touch panel substrate part 11a and the connection part 11b of the substrate 11. This protective layer 14 is formed by spin coating or slit coating, in a manner similar to the insulating layer 13 described above. Unnecessary parts of the protective layer 14 are removed by etching or the like.

### Effects of Embodiment 1

In this embodiment, the protective layer 14 is provided on the operation screen side of the substrate 11 so as to cover the connection section between the touch panel substrate part 11a and the connection part 11b. Thus, in the substrate 11, which is formed of a flexible substrate where the touch panel substrate part 11a and the connection part 11b are formed integrally, the strength of the connection section can be improved. Therefore, it is possible to prevent damage to the connection section when the substrate 11 is deformed.

By providing the protective layer 14 as described above, exposure of the touch electrodes 12 and the lead-out wiring lines 24 on the touch panel substrate part 11a can be prevented, and thus the environmental resistance of the touch panel 2 can be improved.

As described above, by providing the protective layer 14 on the touch panel substrate part 11a, the surface can be smoothed if the operation screen side is covered with a not-shown touch panel film. In this way, it is possible to prevent bubbles from occurring between the touch panel film and the surface of the protective layer 14.

### Embodiment 2

FIG. 5 shows a configuration of portion of a connection part 11b of a substrate 11 in a touch panel 30 according to Embodiment 2. Embodiment 2 differs from the configuration of Embodiment 1 described above in that a protective plate 31 is provided on the connection part 11b. In the description below, the same reference characters are used for configurations the same as Embodiment 1, and only features that differ from Embodiment 1 will be explained.

Specifically, as shown in FIG. 5, the protective plate 31, which is made of a polyimide or another resin material, for example, is formed in the connection part 11b of the substrate 11, on the opposite side (hereinafter, the rear side) of the operation screen side of the touch panel 30. Polyimide is preferable as the material constituting the protective plate 31, due to the shrinkage ratio to heat, required hardness, and the like of the polyimide. The protective plate 31 is for improving the strength of the connection part 11b, and is used when the connection part 11b is connected to a different hard substrate, for example.

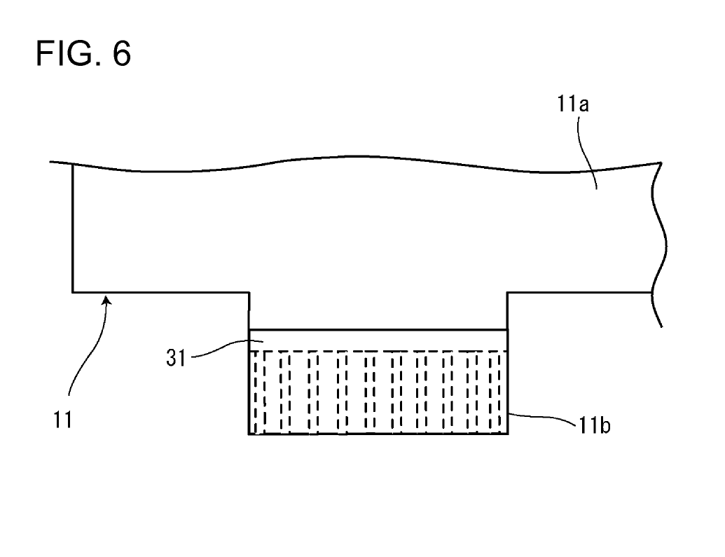

As shown in FIG. 6, the protective plate 31 is formed large enough to cover the terminal part (the part shown by a broken line) of the connection part 11b in a plan view. Specifically, the provided protective plate 31 has a size that is large enough to cover the connection part 11b in a plan view and that allows a prescribed range (a range with a width of approximately 1 mm and extending in a belt-shape along the connector, for example) to be exposed from a not-shown connector, when the connection part 11b is inserted into the connector. Thus, the connection part 11b is reinforced by the protective plate 31. Therefore, when the substrate 11 is bent, disconnection of the terminal part of the connection part 11b can be prevented, and because the connection part 11b can be forcefully pushed into the connector, workability during connecting procedures can be improved. With the configuration described above, the durability of the connection part 11b can be improved, and damage to the connection part 11b can be prevented even when the connection part 11b is repeatedly inserted into and removed from the connector. FIG. 6 is a view as seen from the rear side of the substrate 11.

The protective plate 31 is bonded to the rear side of the connection part 11b using double-sided tape or an adhesive material, in a touch panel manufactured by the manufacturing method shown in Embodiment 1 described above.

### Effects of Embodiment 2

In this embodiment, the strength of the connection part 11b can be improved by providing the protective plate 31 on the connection part 11b of the substrate 11. Therefore, damage to the connection part 11b due to deformation of the substrate 11 or due to insertion in and removal from the connector can be prevented, and connection between the connection part 11b and the connector can be easily performed.

### Embodiment 3

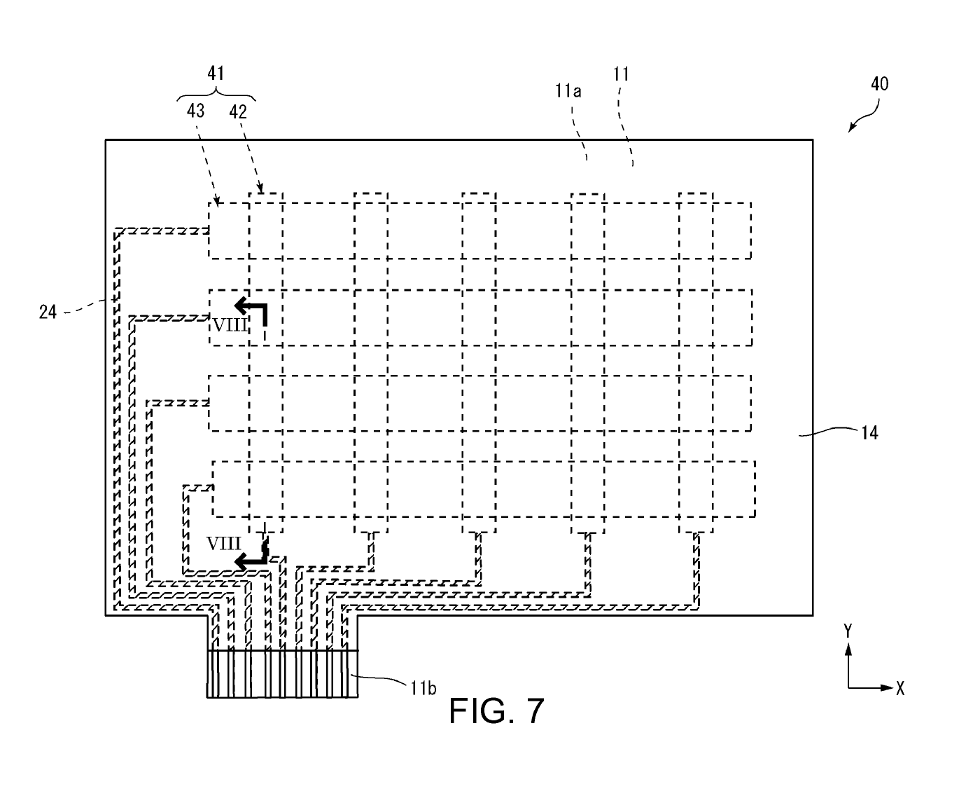

FIG. 7 shows a schematic configuration of a touch panel 40 according to Embodiment 3. This embodiment differs from the configuration of Embodiment 1 in that touch electrodes 41 are provided with two electrodes 42 and 43 that are formed in a rectangular shape and that are arranged so as to intersect with each other. In the description below, the same reference characters are used for configurations the same as Embodiment 1, and only features that differ from Embodiment 1 will be explained.

Specifically, the touch electrodes 41 are provided with Y-direction electrodes 42 that extend in the Y direction, and X-direction electrodes 43 that extend in the X direction in FIG. 7. These Y-direction electrodes 42 and X-direction electrodes 43 are all formed in a substantially rectangular shape. The Y-direction electrodes 42 and the X-direction electrodes 43 are arranged so as to intersect with each other, in a manner similar to Embodiment 1. The X direction is the lengthwise direction of a substrate 11, and the Y direction is the widthwise direction of the substrate 11, in a manner similar to Embodiment 1.

In this embodiment, the X-direction electrodes 43 and the Y-direction electrodes 42 correspond to electrode pads.

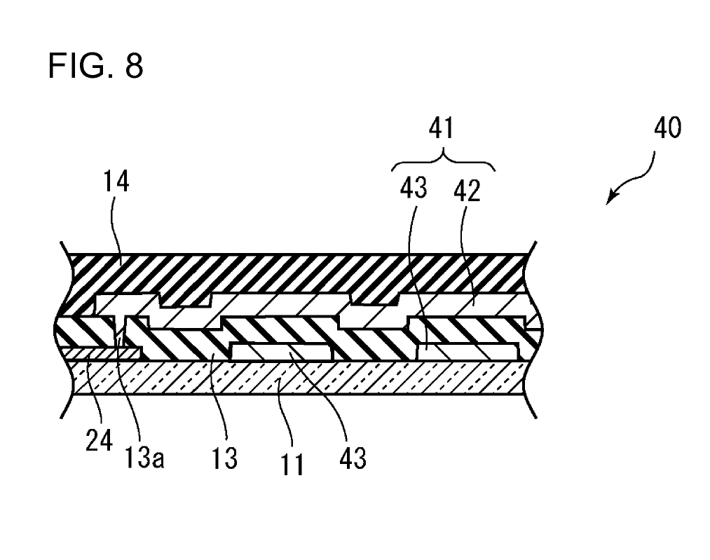

As shown in FIG. 8, the X-direction electrodes 43 are formed on the substrate 11 along with lead-out wiring lines 24. The Y-direction electrodes 42 are formed on an insulating layer 13 that is formed on the X-direction electrodes 43. In other words, the X-direction electrodes 43 and the Y-direction electrodes 42 are formed so as to sandwich the insulating layer 13. A contact hole 13a is formed in this insulating layer 13 for electrically connecting the Y-direction electrodes 42 to the lead-out wiring lines 24.

With this configuration, the Y-direction electrodes 42 and X-direction electrodes 43 can be provided intersecting with each other without short-circuiting.

This embodiment also has a protective layer 14 formed on a touch panel substrate part 11a, and on the connection section between the touch panel substrate part 11a and a connection part 11b of the substrate 11, so as to cover the operation screen side of the panel, in a manner similar to Embodiment 1 described above. Thus, the strength of the connection section can be improved, and the environmental resistance of the touch electrodes 41 and the lead-out wiring lines 24 can be improved.

Next, a manufacturing method for the touch panel 40 having a configuration as described above will be explained with reference to FIGS. 7 and 8.

First, the substrate 11 is formed in which the touch panel substrate part 11a and the connection part 11b are integrated. Then, a metal layer is formed by depositing an aluminum alloy using CVD (Chemical Vapor Deposition), sputtering, or the like on the touch panel substrate part 11a. By photolithography, a resist pattern is formed to cover planned formation areas of the lead-out wiring lines 24, and the metal layer is etched with this as the mask. Thus, the lead-out wiring lines 24 as shown in FIG. 7 are obtained. Then, the formed resist pattern is removed.

Next, a transparent metal film made of a transparent conductive material such as ITO or IGZO is formed on the substrate 11 by CVD, sputtering, or the like. By photolithography, a resist pattern is formed to cover the planned formation areas of the X-direction electrodes 43, and the transparent metal film is etched with this as the mask. Then, the formed resist pattern is removed.

Then, the insulating layer 13 is formed so as to cover the substrate 11, the X-direction electrodes 43 and the lead-out wiring lines 24 (see FIG. 8). This insulating layer 13 is made of an acrylic resin or the like, for example. This insulating layer 13 is formed by spin coating or slit coating.

Next, a resist pattern that covers the areas other than the planned formation areas of the contact hole 13a is formed on the touch panel substrate part 11a by photolithography, and the insulating layer 13 is etched with this as the mask. Thus, the insulating layer 13 is removed from areas other than the touch panel substrate part 11a, and the contact hole 13a is formed in the insulating layer 13 (see FIG. 8). Then, the resist pattern on the insulating layer 13 is removed.

A transparent metal film made of a transparent conductive material such as ITO or IGZO is formed on the insulating layer 13 by CVD, sputtering, or the like. By photolithography, a resist pattern is formed to cover the planned formation areas of the Y-direction electrodes 42, and the transparent metal film is etched with this as the mask. Thus, the touch electrodes 41 as shown in FIG. 7 are obtained. Then, the formed resist pattern is removed.

Then, as shown in FIGS. 7 and 8, a protective layer 14 made of an acrylic resin, for example, is formed on the touch panel substrate part 11a, and the connection section between the touch panel substrate part 11a and the connection part 11b of the substrate 11. This protective layer 14 is also formed by spin coating or slit coating, in a manner similar to the insulating layer 13 described above. Unnecessary parts of the protective layer 14 are removed by etching or the like.

### Effects of Embodiment 3

In this embodiment, the protective layer 14 is provided on the touch panel substrate 1 la and on the connection section between the touch panel substrate 11a and the connection part 11b, in a touch panel 40 where the touch electrodes 41 are constituted of the substantially rectangular X-direction electrodes 43 and Y-direction electrodes 42 being arranged to intersect with each other. Thus, the strength of the connection section between the touch panel substrate part 11a and the connection part 11b on the substrate 11 can be improved. The environmental resistance of the touch electrodes 41 and the lead-out wiring lines 24 formed on the substrate 11 can be improved by the protective layer 14.

### Other Embodiments

Embodiments of the present invention have been described above, but the above embodiments are mere examples of implementations of the present invention. The present invention is not limited to the above embodiments, and can be implemented by appropriately modifying the above embodiments without departing from the spirit thereof.

In each embodiment, the X-direction electrodes 22 and 43 and the Y-direction electrodes 21 and 42 are made of ITO or IGZO, but the X-direction and Y-direction electrodes are not limited to these, and may also be made of a different transparent conductive material.

In each embodiment, the X-direction electrodes 22 and 43 and the Y-direction electrodes 21 and 42 are transparent electrodes, but the X-direction and Y-direction electrodes are not limited to this, and may also be a metal material such as an aluminum alloy. When the X-direction electrodes and Y-direction electrodes are made of a metal material as such, the X-direction electrodes and Y-direction electrodes would be susceptible to effects of the external environment, such as corroding easily. However, by providing the protective layer 14 as in each embodiment described above, the environmental resistance can be improved. In other words, when the X-direction electrodes and Y-direction electrodes are made of a metal material, the configuration in each embodiment described above is effective in that the environmental resistance is improved compared to a configuration in which the electrodes are made of ITO or the like.

In Embodiment 1, the bridge parts 23 that connect the X-direction electrode pads 22a and 22b together are made of a metal material such as an aluminum alloy. However, the bridge parts 23 may also be made of a transparent conductive material such as ITO or IGZO.

As described above, when a metal material is used instead of a transparent conductive material such as ITO, the resistivity can be lowered more than with ITO. However, problems occur such as the electrodes being easily visible, increased possibility of moire, and a partial lowering of transmittance. Therefore, it is preferable for the X-direction electrodes, the Y-direction electrodes, the bridge parts, the lead-out wiring lines, and the like to be made of a metal material formed in a stripe or grid pattern. Thus, it is possible to make the moire and transmittance uniform, and to make it harder to see the electrode patterns.

In each embodiment, the protective layer 14 was made of an acrylic resin, but the protective layer 14 is not limited to this, and may be made of a different material as long as it is a material that can improve the strength of the connection section of the touch panel substrate part 11a and the connection part 11b of the substrate 11.

In each embodiment, the protective layer 14 is provided on the touch panel substrate part 11a, and the connection section between the touch panel substrate part 11a and the connection part 11b. However, the protective layer 14 may also be provided on just the connection section between the touch panel substrate 11a and the connection part 11b.

In each embodiment, the X-direction electrodes 22 and 43, and the Y-direction electrodes 21 and 42 are formed in a substantially triangular shape or a rectangular shape. However, the X-direction electrodes and the Y-direction electrodes may also be formed in other shapes, such as a polygonal shape or a circle.

### INDUSTRIAL APPLICABILITY

The touch panel according to the present invention can be used for a touch panel using a panel substrate that has overall flexibility and that has a panel part, in which electrode pads are provided, and a protrusion part, in which some lead-out wiring lines are placed, formed integrally with each other.

1. A touch panel, comprising:
a panel substrate having flexibility, the panel substrate having a panel part and a protrusion part formed integrally with the panel part;
a plurality of electrode pads disposed on the panel part so as to be capable of detecting a touch location;
lead-out wiring lines disposed on the panel part and the protrusion part, the lead-out wiring lines being electrically connected with the electrode pads and externally outputting signals generated in the electrode pads from the protrusion part; and
a transparent protective layer for improving strength disposed on an operation screen side of a connection section between the panel part and the protrusion part.

2. The touch panel according to claim 1, wherein the protective layer is also formed on the panel part.

3. The touch panel according to claim 1, wherein the electrode pads are made of indium tin oxide or indium gallium zinc oxide.

4. The touch panel according to claim 1, further comprising a protective plate disposed overlapping the protrusion part in the thickness direction.
